(19) United States
(12) Patent Application Publication
(10) Pub. No.: US 2022/0050572 A1
(43) Pub. Date: Feb. 17, 2022

(54) TOUCH DISPLAY DEVICE

(71) Applicant: Au Optronics Corporation, Hsinchu (TW)

(72) Inventors: Cheng-Ying Chou, Hsinchu (TW); Jian Cheng Liou, Hsinchu (TW)

(73) Assignee: Au Optronics Corporation, Hsinchu (TW)

(21) Appl. No.: 17/129,927

(22) Filed: Dec. 22, 2020

(30) Foreign Application Priority Data
Aug. 11, 2020 (TW) 109127219

(51) Int. Cl. G06F 3/041; G06F 3/044; H03K 17/96

(52) U.S. Cl. CPC G06F 3/04166; G06F 3/04164; H03K 2017/9604; H03K 17/962; G06F 2203/04107; G06F 3/0443

(57) ABSTRACT

A touch display device, including a display panel and a touch panel, is provided. The touch panel has a first display area, a second display area, and a connection area located therebetween, and includes a substrate, first touch signal lines, second touch signal lines, first electrode lines, second electrode lines, and first connection lines. The first and second touch signal lines are located on the first display area. The first and second electrode lines are located on the second display area. The first connection lines are located on the connection area. The first touch signal lines, the first electrode lines, and the first connection lines extend along a first direction. The first connection lines are electrically connected to the first touch signal lines and at least part of the first electrode lines. The second touch signal lines and the second electrode lines extend along a second direction.

### CROSS-REFERENCE TO RELATED APPLICATION

This application claims the priority benefit of Taiwan application serial no. 109127219, filed on Aug. 11, 2020. The entirety of the above-mentioned patent application is hereby incorporated by reference herein and made a part of this specification.

### BACKGROUND

### Technical Field

The invention relates to a touch display device, and particularly relates to a touch display device having a display panel and a touch panel.

### Description of Related Art

Along with development of technology, appearance rate of touch devices and various related technologies on the market has gradually increased. In some touch display devices, different areas have different functions due to different requirements. For example, in a car touch display panel, only a display function is needed in a dashboard area without a touch function. In an area of an operation panel, both of the display function and the touch function are required. Generally, a plurality of touch panels are respectively attached on the display panel at a plurality of positions requiring the touch function, so that a touch display panel only has the touch function in specific areas.

### SUMMARY

The invention is directed to a touch display device, which is capable of reducing attaching times of a touch panel.

The invention is directed to a touch display device, which is capable of reducing attaching times of a touch panel and reducing a transmittance difference of the touch display device in different display areas.

At least one embodiment of the invention provides a touch display device including a display panel and a touch panel. The touch panel is overlapped with the display panel, and has a first display area, a second display area, and a first connection area located between the first display area and the second display area. The touch panel includes a substrate, a plurality of first touch signal lines, a plurality of second touch signal lines, a plurality of first electrode lines, a plurality of second electrode lines, and a plurality of first connection lines. The first touch signal lines and the second touch signal lines are located on the first display area. The first electrode lines and the second electrode lines are located on the second display area. The first touch signal lines and the first electrode lines extend along a first direction. The second touch signal lines and the second electrode lines extend along a second direction. Materials of the first touch signal lines, the second touch signal lines, the first electrode lines and the second electrode lines include a transparent conductive material. The first connection lines are located on the first connection area, and extend along the first direction. The first connection lines are electrically connected to the first touch signal lines and at least part of the first electrode lines.

The invention provides a touch display device including a display panel and a touch panel. The touch panel is overlapped with the display panel, and has a first display area, a second display area, and a first connection area located between the first display area and the second display area. The touch panel includes a substrate, a plurality of first touch signal lines, a plurality of second touch signal lines, a plurality of first electrode lines, a plurality of second electrode lines, at least one driving chip and a plurality of first connection lines. The first touch signal lines and the second touch signal lines are located on the first display area. The first touch signal lines extend along a first direction. The second touch signal lines extend along a second direction. The first electrode lines and the second electrode lines are located on the second display area. The first electrode lines extend along the first direction. The second electrode lines extend along the second direction. The driving chip is disposed at a first side of the first connection area. The first connection lines are located on the first connection area, and electrically connect the first touch signal lines to the at least one driving chip. The first connection lines extend from the first display area into the first connection area in a direction parallel to the first direction, and at least part of the first connection lines is turned toward the first side in the first connection area. Materials of the first touch signal lines, the first connection lines and the first electrode lines include a transparent conductive material.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a touch display device according to the invention.

FIG. 2 is a schematic top view of a display panel according to the invention.

FIG. 3A is a schematic top view of a touch panel according to the invention.

FIG. 3B is a schematic partial enlarged view of FIG. 3A.

FIG. 4 is a schematic top view of a touch panel according to the invention.

FIG. 5 is a schematic top view of a touch panel according to the invention.

FIG. 6 is a schematic top view of a touch panel according to the invention.

FIG. 7 is a schematic top view of a touch panel according to the invention.

FIG. 8 is a schematic top view of a touch panel according to the invention.

FIG. 9 is a schematic top view of a touch panel according to the invention.

FIG. 10 is a schematic top view of a touch panel according to the invention.

FIG. 11 is a schematic top view of a touch panel according to the invention.

FIG. 12A is a schematic top view of a touch panel according to the invention.

FIG. 12B is a schematic cross-sectional view of FIG. 12A viewing along a line aa′.

FIG. 13 is a schematic top view of a touch panel according to the invention.

### DESCRIPTION OF THE EMBODIMENTS

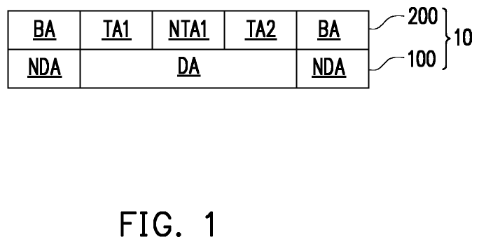

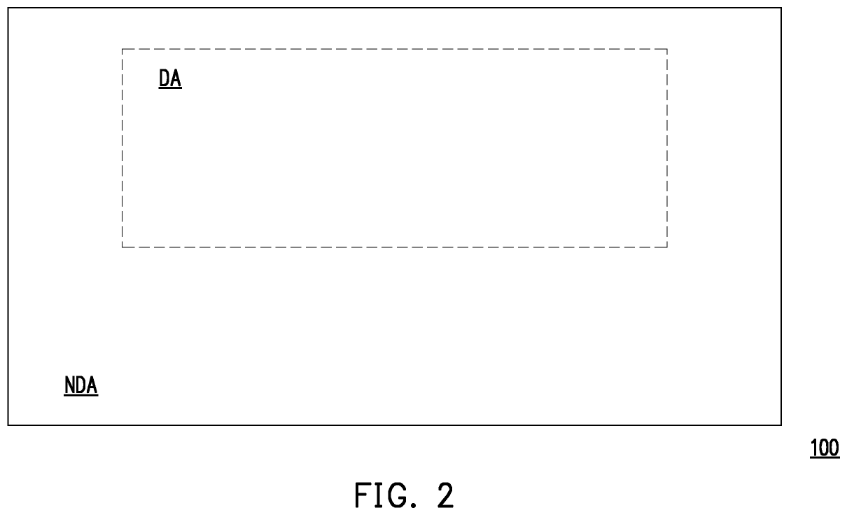

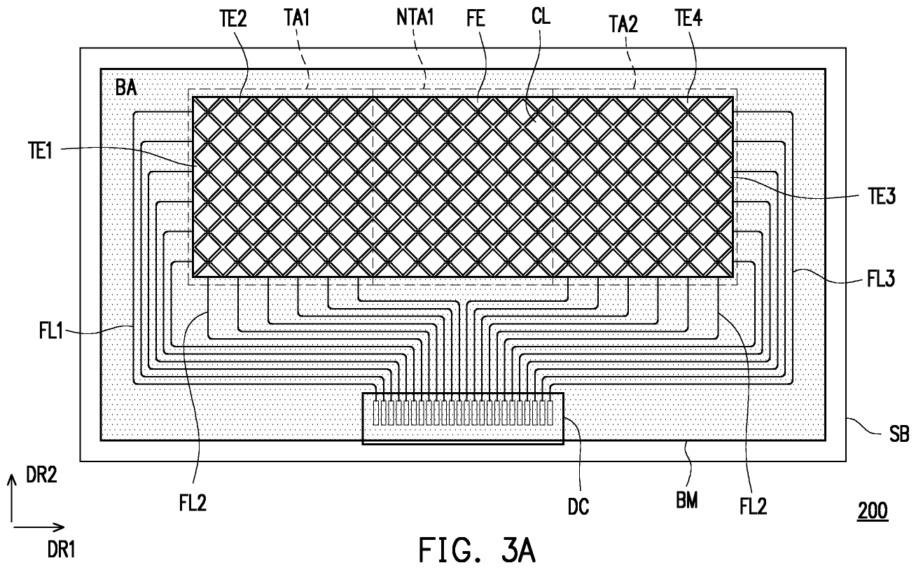

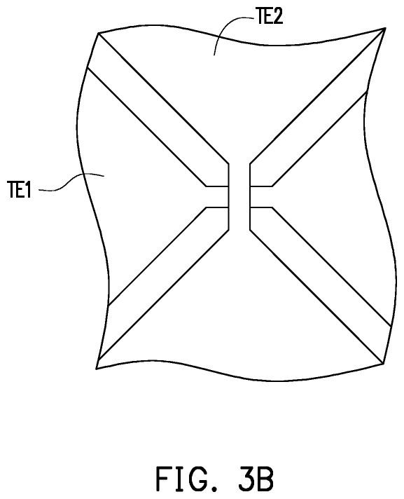

FIG. 1 is a schematic cross-sectional view of a touch display device according to the invention. FIG. 2 is a schematic top view of a display panel according to the invention. FIG. 3A is a schematic top view of a touch panel according to the invention. FIG. 3B is a schematic partial enlarged view of FIG. 3A.

Referring to FIG. 1 to FIG. 3, the touch display device 10 includes a display panel 100 and a touch panel 200.

The display panel 100 has a display area DA and a non-display area NDA. The display panel 100 is, for example, an organic light-emitting diode (OLED) display panel, a micro-LED display panel, or a liquid crystal display panel. In some embodiments, the display panel 100 is a liquid crystal display panel, and the touch display device 10 further includes a backlight module.

The touch panel 200 is overlapped with the display panel 100 and has a first display area TA1, a second display area TA2, and a first connection area NTA1 located between the first display area TA1 and the second display area TA2. In the embodiment, the first display area TA1, the second display area TA2, and the first connection area NTA1 are overlapped with the display area DA of the display panel 100.

Referring to FIG. 3, the touch panel 200 includes a substrate SB, a plurality of first touch signal lines TE1, a plurality of second touch signal lines TE2, a plurality of first electrode lines TE3, and a plurality of second electrode lines TE4 and a plurality of first connection lines CL. In the embodiment, the touch panel 200 further includes at least one driving chip DC, a plurality of floating electrodes FE, a light-shielding layer BM, a plurality of first circuit lines FL1, a plurality of second circuit lines FL2, and a plurality of third circuits lines FL3.

The first touch signal lines TE1 and the second touch signal lines TE2 are located on the first display area TA1. The first touch signal lines TE1 extend along a first direction DR1. The second touch signal lines TE2 extend along a second direction DR2. The first touch signal lines TE1 and the second touch signal lines TE2 are staggered. In the embodiment, one of the first touch signal line TE1 and the second touch signal line TE2 is a driving line (TX), and the other is a sensing line (RX).

The first electrode lines TE3 and the second electrode lines TE4 are located on the second display area TA2. The first electrode lines TE3 extend along the first direction DR1. The second electrode lines TE4 extend along the second direction DR2. The first electrode lines TE3 and the second electrode lines TE4 are staggered. In the embodiment, one of the first electrode line TE3 and the second electrode line TE4 is a driving line, and the other is a sensing line.

The first connection lines CL and the floating electrodes FE are located on the first connection area NTA1, and the first connection lines CL extend along the first direction DR1. The floating electrodes FE extend along the second direction DR2. The first connection lines CL and the floating electrodes FE are staggered. The first connection lines CL are electrically connected to the first touch signal lines TE1 and the first electrode lines TE3. The first touch signal lines TE1 and the first electrode lines TE3 are electrically connected to each other. In the embodiment, the first touch signal lines TE1, the first connection lines CL, and the first electrode lines TE3 include a same material, and each first touch signal line TE1, a corresponding first connection line CL, and a corresponding first electrode line TE3 are connected as a whole. For example, the first touch signal lines TE1, the first connection lines CL, and the first electrode lines TE3 are formed in a same patterning process. The second touch signal lines TE2, the floating electrodes FE, and the second electrode lines TE4 include a same material. For example, the second touch signal lines TE2, the floating electrodes FE, and the second electrode lines TE4 are formed in a same patterning process. Referring to FIG. 3B, in the embodiment, the first touch signal lines TE1, the first connection lines CL and the first electrode lines TE3 are separated from the second touch signal lines TE2, the floating electrodes FE, and the second electrode lines TE4. For example, an insulating layer (not shown) is provided so that the first touch signal lines TE1, the first connection lines CL, and the first electrode lines TE3 are not in contact with the second touch signal lines TE2, the floating electrodes FE, and the second electrode lines TE4.

In the embodiment, the first touch signal lines TE1, the second touch signal lines TE2, the first electrode lines TE3, the second electrode lines TE4, the floating electrodes FE, and the first connection lines CL include a transparent conductive material. In the embodiment, the transparent conductive material in the first display area TA1, the second display area TA2, and the first connection area NTA1 makes the first display area TA1, the second display area TA2, and the first connection area NTA1 to have a close transmittance, which reduce a transmittance difference of the touch display device 10 in the first display area TA1, the second display area TA2, and the first connection area NTA1.

The at least one driving chip DC, the first circuit lines FL1, the second circuit lines FL2, and the third circuit lines FL3 are arranged on the peripheral area BA of the substrate, where the peripheral area BA is located outside the first display area TA1 and the second display area TA2 and the first connection area NTA1. In the embodiment, the touch display device, for example, has one driving chip DC, but the invention is not limited thereto. In other embodiments, the touch display device may have a plurality of driving chips DC. The driving chip DC is, for example, electrically connected to the first circuit lines FL1, the second circuit lines FL2, and the third circuit lines FL3 through a flexible circuit board (not shown). The driving chip DC is arranged close to one side of the substrate SB.

The first circuit lines FL1 electrically connect the driving chip DC to the first touch signal lines TE1. The second circuit lines FL2 electrically connect the driving chip DC to the second touch signal lines TE2 and the second electrode lines TE4. The third circuit lines FL3 electrically connect the driving chip DC to the first electrode lines TE3.

The light-shielding layer BM is disposed on the peripheral area BA, and the light-shielding layer BM exposes the first display area TA1, the first connection area NTA1, and the second display area TA2.

In the embodiment, an image formed on the display area DA of the display panel 100 may penetrate through the first display area TA1, the first connection area NTA1, and the second display area TA2. In other words, the touch display panel 10 has a display function in areas corresponding to the first display area TA1, the first connection area NTA1, and the second display area TA2. In the embodiment, the first display area TA1 and the second display area TA2 have a touch function, while the first connection area NTA1 does not have the touch function.

Based on the above description, only one touch panel 200 is required to be attached to the display panel 100, and the touch display panel 10 may have a plurality of touch areas separated from each other.

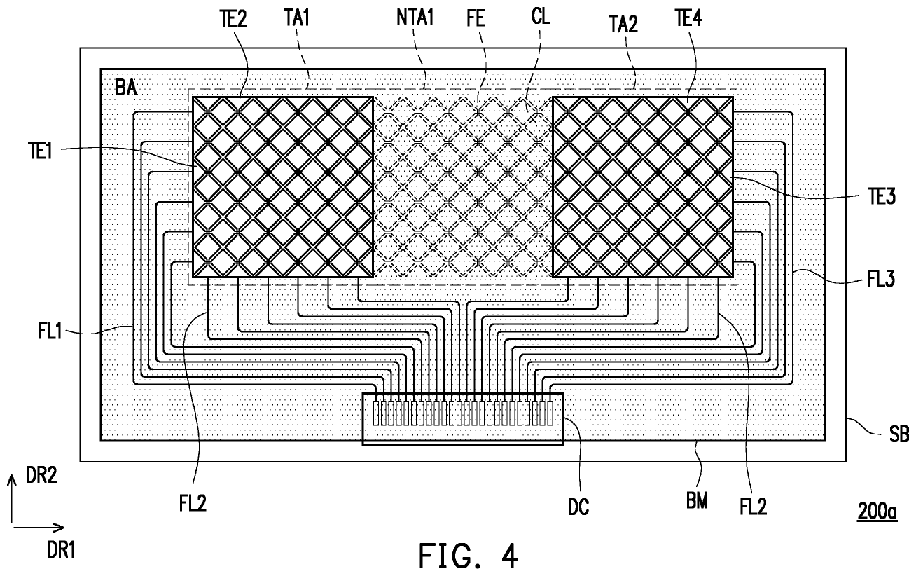

FIG. 4 is a schematic top view of a touch panel according to the invention. It should be noted that reference numbers of the components and a part of contents of the embodiment of FIG. 1 to FIG. 3B are also used in the embodiment of FIG. 4, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200a of FIG. 4 and the touch panel 200 of FIG. 3A is that the light-shielding layer BM of the touch panel 200a is disposed on the peripheral area BA and the first connection area NTA1, and the light-shielding layer BM exposes the first display area TA1 and the second display area TA2.

In the embodiment, the touch display panel has the display function in areas corresponding to the first display area TA1 and the second display area TA2, but does not have the display function in the area corresponding to the first connection area NTA1. In the embodiment, the first display area TA1 and the second display area TA2 have a touch function, while the first connection area NTA1 does not have the touch function.

Based on the above description, only one touch panel 200a is required to be attached to the display panel, and the touch display panel may have a plurality of touch areas separated from each other.

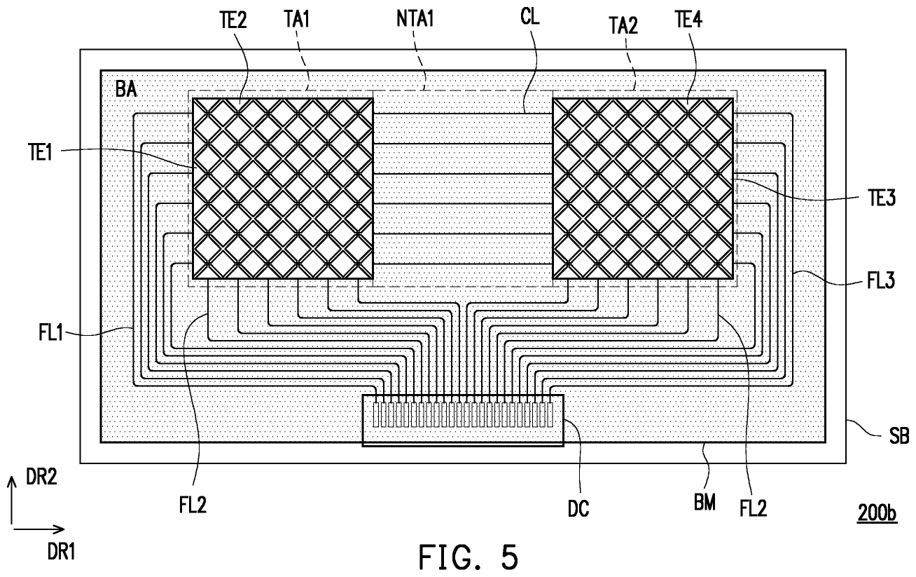

FIG. 5 is a schematic top view of a touch panel according to the invention. It should be noted that reference numbers of the components and a part of contents of the embodiment of FIG. 4 are also used in the embodiment of FIG. 5, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200b of FIG. 5 and the touch panel 200a of FIG. 4 is that the first connection lines CL of the touch panel 200b include metal wires.

In the embodiment, the first touch signal lines TE1, the first connection lines CL, and the first electrode lines TE3 are sequentially connected.

In the embodiment, the touch display panel has the display function in areas corresponding to the first display area TA1 and the second display area TA2, but does not have the display function in the area corresponding to the first connection area NTA1. In the embodiment, the first display area TA1 and the second display area TA2 have the touch function, while the first connection area NTA1 does not have the touch function.

Based on the above description, only one touch panel 200b is required to be attached to the display panel, and the touch display panel may have a plurality of touch areas separated from each other.

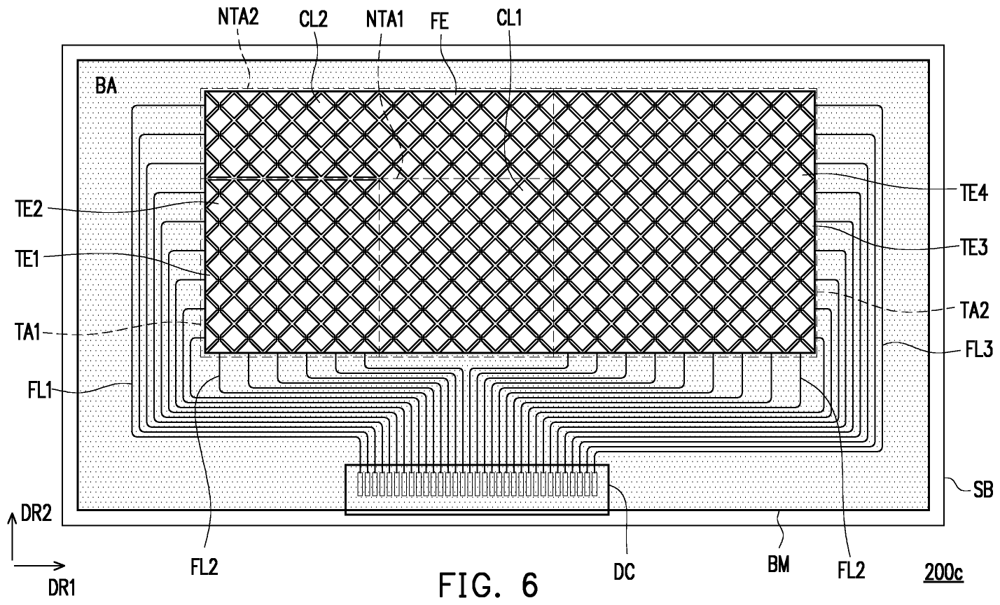

FIG. 6 is a schematic top view of a touch panel according to the invention. It should be noted that reference numbers of the components and a part of contents of the embodiment of FIG. 1 to FIG. 3B are also used in the embodiment of FIG. 6, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200c in FIG. 6 and the touch panel 200 in FIG. 3A is that an area of the first display area TA1 of the touch panel 200c is smaller than an area of the second display area TA2.

In the embodiment, the touch panel 200c includes first connection lines CL1 and second connection lines CL2. The first connection lines CL1 and the second connection lines CL2 extend along the first direction DR1. The first connection lines CL1 are located on the first connection area NTA1, and the second connection lines CL2 are located on the second connection area NTA2. In the first direction DR1, the second connection area NTA2 is located between the peripheral area BA and the second display area TA2. In the embodiment, the first connection lines CL1 and the second connection lines CL2 include a transparent conductive material, and the first connection lines CL1 and the second connection lines CL2 are formed in a same patterning process.

The first connection lines CL1 are electrically connected to the first touch signal lines TE1 and a part of the first electrode lines TE3. The second connection lines CL2 are electrically connected to a part of the first circuit lines FL1 and another part of the first electrode lines TE3. The second connection lines CL2 are aligned with the aforementioned another part of the first electrode lines TE3 in the first direction DR1.

In the embodiment, the floating electrodes FE are located on the first connection area NTA1 and the second connection area NTA2. The floating electrodes FE extend along the second direction DR2, and are staggered with the first connection lines CL1 and the second connection lines CL2. A part of the floating electrode FE is aligned with the second touch signal lines TE2 in the second direction DR, and is separated from the second touch signal lines TE2.

In the embodiment, the touch display panel has the display function in areas corresponding to the first display area TA1, the second display area TA2, the first connection area NTA1, and the second connection area NTA2. In the embodiment, the first display area TA1 and the second display area TA2 have the touch function, while the first connection area NTA1 and the second connection area NTA2 do not have the touch function.

Based on the above description, only one touch panel 200c is required to be attached to the display panel, and the touch display panel may have a plurality of touch areas separated from each other.

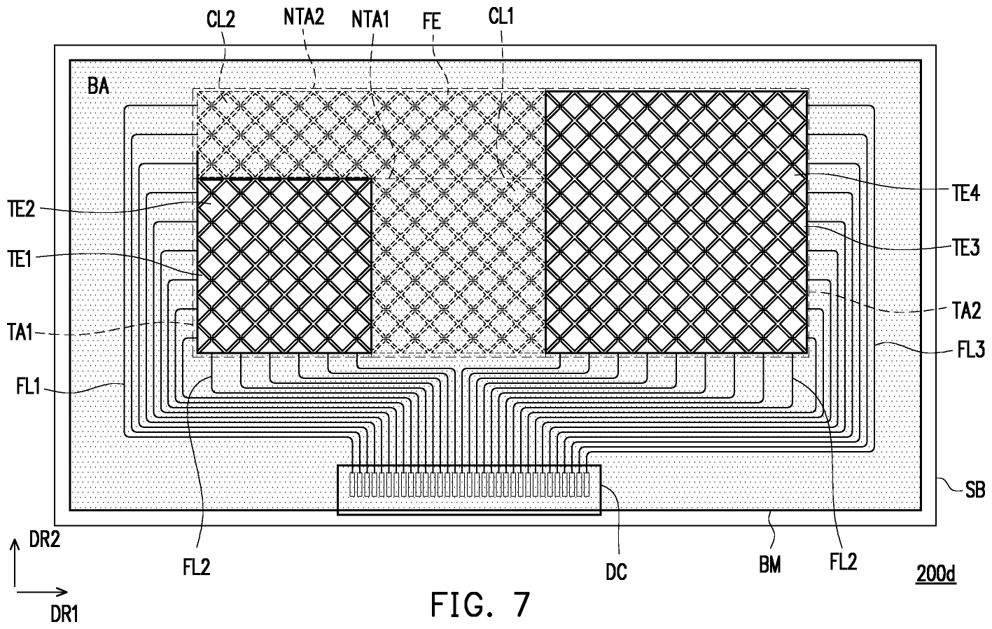

FIG. 7 is a schematic top view of a touch panel according to the invention. It should be noted that reference numbers of the components and a part of contents of the embodiment of FIG. 6 are also used in the embodiment of FIG. 7, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200d of FIG. 7 and the touch panel 200c of FIG. 6 is that the light-shielding layer BM of the touch panel 200d is disposed on the peripheral area BA, the first connection area NTA1 and the second connection area NTA2, and the light-shielding layer BM exposes the first display area TA1 and the second display area TA2.

In the embodiment, the touch display panel has the display function in areas corresponding to the first display area TA1 and the second display area TA2, but does not have the display function in areas corresponding to the first connection area NTA1 and the second connection area NTA2. In the embodiment, the first display area TA1 and the second display area TA2 have the touch function, while the first connection area NTA1 and the second connection area NTA2 do not have the touch function.

Based on the above description, only one touch panel 200d is required to be attached to the display panel, and the touch display panel may have a plurality of touch areas separated from each other.

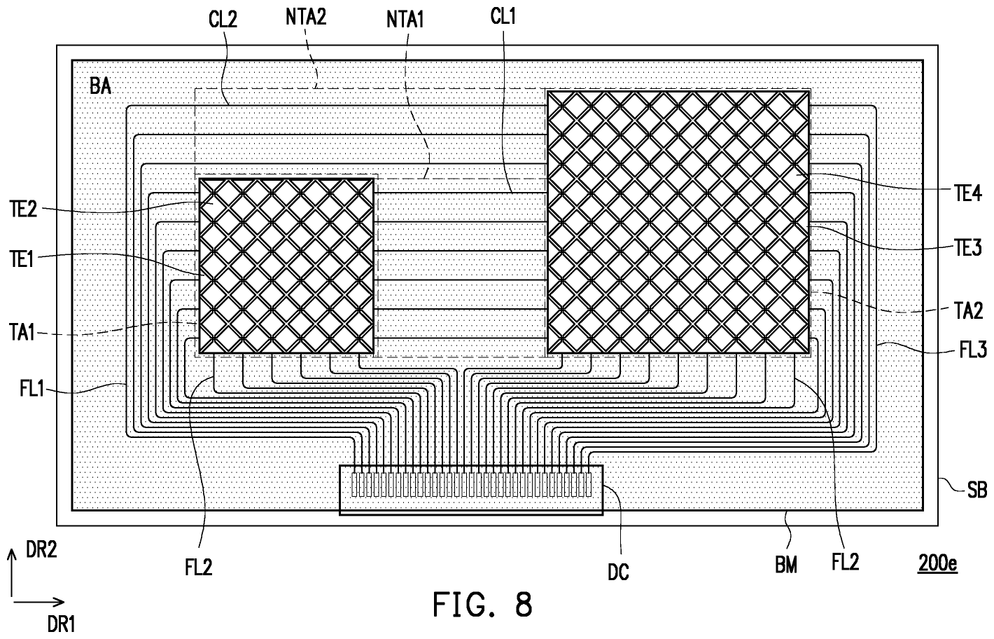

FIG. 8 is a schematic top view of a touch panel according to the invention. It should be noted that reference numbers of the components and a part of contents of the embodiment of FIG. 7 are also used in the embodiment of FIG. 8, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200e of FIG. 8 and the touch panel 200d of FIG. 7 is that the first connection line CL1 and the second connection line CL2 of the touch panel 200e include metal wires.

In the embodiment, the first connection lines CL1 are electrically connected to the first touch signal lines TE1 and a part of the first electrode lines TE3. The second connection lines CL2 are electrically connected to a part of the first circuit lines FL1 and another part of the first electrode lines TE3. The second connection lines CL2 are aligned with the aforementioned another part of the first electrode lines TE3 in the first direction DR1.

In the embodiment, the second connection lines CL2 and a part of the first circuit lines FL1 are connected as a whole. For example, the first connection lines CL1, the second connection lines CL2, the first circuit lines FL1, the second circuit lines FL2, and the third circuit lines FL3 are formed in a same patterning process.

In the embodiment, the touch display panel has the display function in areas corresponding to the first display area TA1 and the second display area TA2, but does not have the display function in areas corresponding to the first connection area NTA1 and the second connection area NTA2. In the embodiment, the first display area TA1 and the second display area TA2 have the touch function, while the first connection area NTA1 and the second connection area NTA2 do not have the touch function.

Based on the above description, only one touch panel 200e is required to be attached to the display panel, and the touch display panel may have a plurality of touch areas separated from each other.

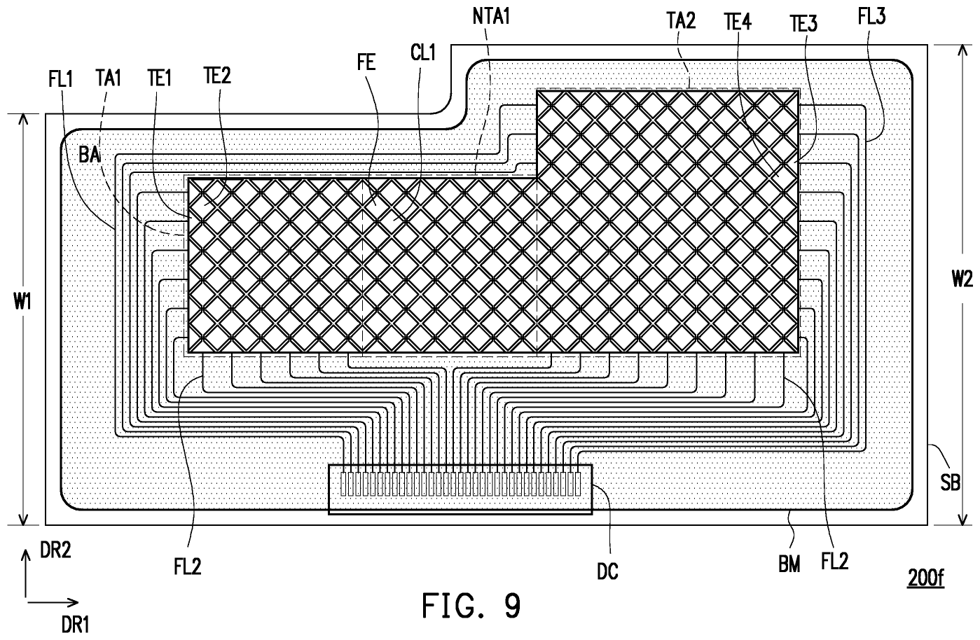

FIG. 9 is a schematic top view of a touch panel according to the invention. It should be noted that reference numbers of the components and a part of contents of the embodiment of FIG. 6 are also used in the embodiment of FIG. 9, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200f of FIG. 9 and the touch panel 200c of FIG. 6 is that the substrate SB of the touch panel 200f is a special-shaped substrate.

In the embodiment, an area of the first display area TA1 is smaller than an area of the second display area TA2, and a width W1 of the substrate SB at the first display area TA1 is smaller than a width W2 of the substrate SB at the second display area TA2.

A part of the first circuit lines FL1 and the first connection lines CL1 are respectively connected to the first electrode line TE3. Another part of the first circuit lines FL1 is connected to the first touch signal lines TE1.

Based on the above description, only one touch panel 200f is required to be attached to the display panel, and the touch display panel may have a plurality of touch areas separated from each other.

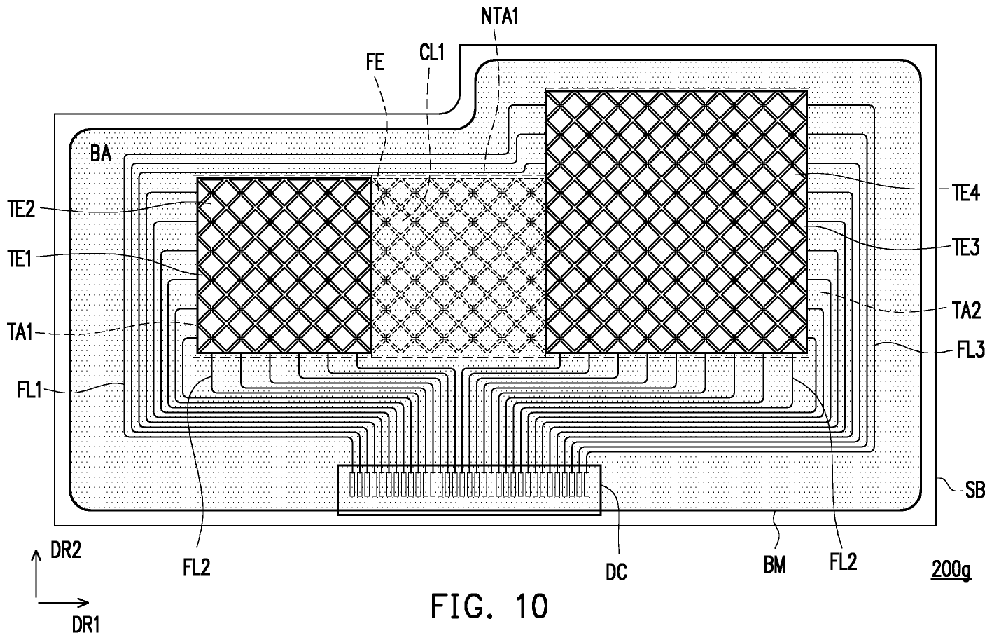

FIG. 10 is a schematic top view of a touch panel according to the invention. It should be noted that reference numbers of the components and a part of contents of the embodiment of FIG. 9 are also used in the embodiment of FIG. 10, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200g of FIG. 10 and the touch panel 200f of FIG. 9 is that the light-shielding layer BM of the touch panel 200g is disposed on the peripheral area BA and the first connection area NTA1, and the light-shielding layer BM exposes the first display area TA1 and the second display area TA2.

In the embodiment, the touch display panel has the display function in areas corresponding to the first display area TA1 and the second display area TA2, but does not have the display function in the area corresponding to the first connection area NTA1. In the embodiment, the first display area TA1 and the second display area TA2 have the touch function, while the first connection area NTA1 does not have the touch function.

Based on the above description, only one touch panel 200g is required to be attached to the display panel, and the touch display panel may have a plurality of touch areas separated from each other.

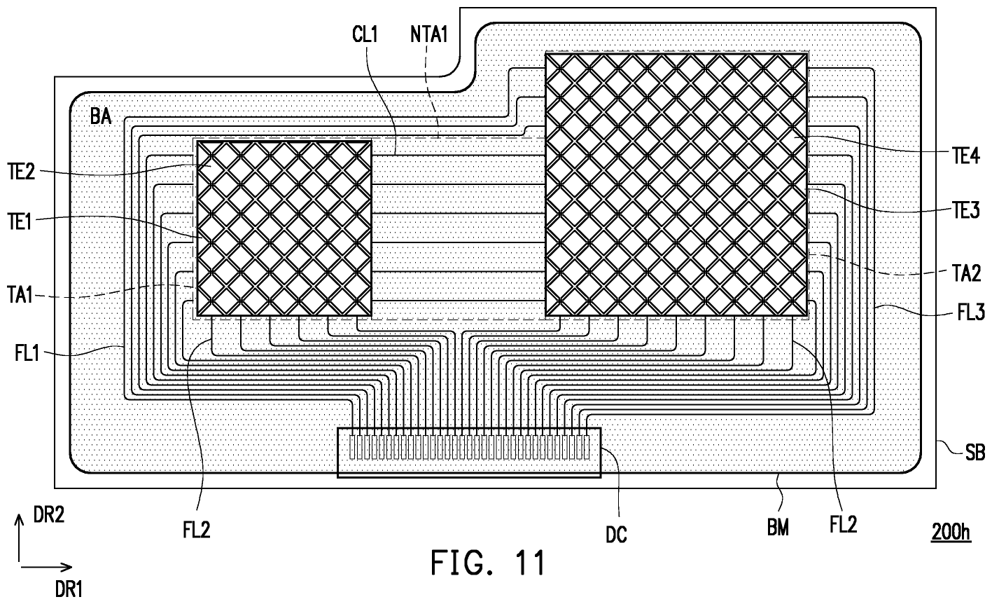

FIG. 11 is a schematic top view of a touch panel according to the invention. It should be noted that reference numbers of the components and a part of contents of the embodiment of FIG. 10 are also used in the embodiment of FIG. 11, where the same reference numbers denote the same or like components, and descriptions of the same technical contents are omitted. The aforementioned embodiment may be referred for descriptions of the omitted parts, and detailed descriptions thereof are not repeated in the following embodiment.

A main difference between a touch panel 200h of FIG. 11 and the touch panel 200g of FIG. 10 is that the first connection lines CL1 of the touch panel 200h include metal wires.

In an embodiment, the first connection lines CL1 are electrically connected to the first touch signal lines TE1 and a part of the first electrode lines TE3.

In the embodiment, the touch display panel has the display function in areas corresponding to the first display area TA1 and the second display area TA2, but does not have the display function in the area corresponding to the first connection area NTA1. In the embodiment, the first display area TA1 and the second display area TA2 have the touch function, while the first connection area NTA1 does not have the touch function.

Based on the above description, only one touch panel 200h is required to be attached to the display panel, and the touch display panel may have a plurality of touch areas separated from each other.

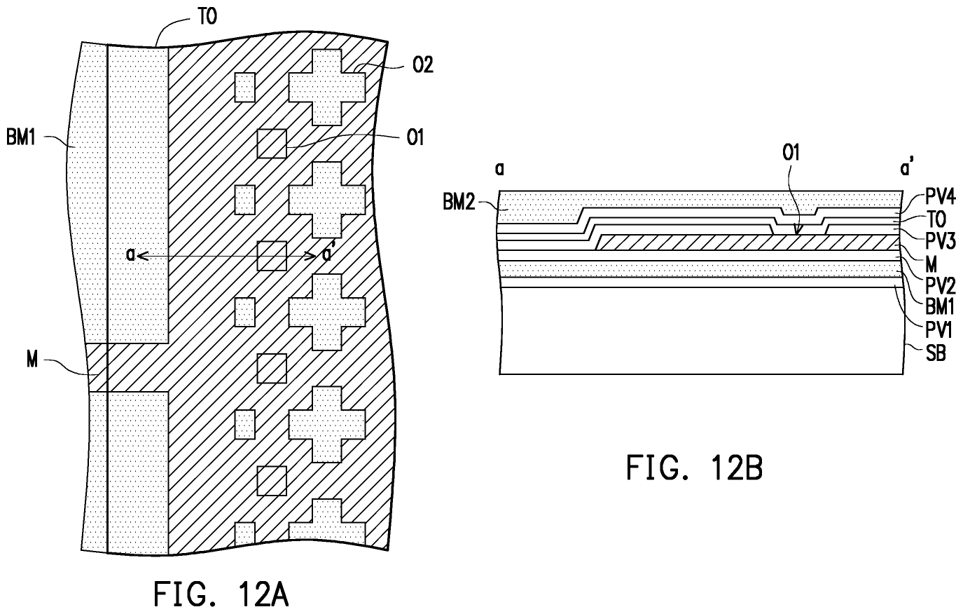

FIG. 12A is a schematic top view of a touch panel according to the invention. FIG. 12B is a schematic cross-sectional view of FIG. 12A viewing along a line aa′.

FIGS. 12A and 12B are used to illustrate the connection between the metal wire M and the transparent conductive material TO of the touch panel. The metal wire M is, for example, the first circuit line, the second circuit line, the third circuit line, the first connection line, or the second connection line of the aforementioned embodiment. The transparent conductive material TO is, for example, the first touch signal line, the second touch signal line, the first electrode line, or the second electrode line of the aforementioned embodiment.

Referring to FIG. 12A and FIG. 12B, the touch panel includes a substrate SB, a light-shielding layer BM1, a passivation layer PV2, the metal wire M, a passivation layer PV3, the transparent conductive material TO, and a passivation layer PV4. In some embodiments, the touch panel selectively includes a passivation layer PV1 and a light-shielding layer BM2.

In an embodiment, the passivation layer PV1, the light-shielding layer BM1, the passivation layer PV2, the metal wire M, the passivation layer PV3, the transparent conductive material TO, the passivation layer PV4, and the light-shielding layer BM2 are sequentially stacked on the substrate SB. The passivation layer PV3 has a plurality of openings O1, and the transparent conductive material TO is electrically connected to the metal wire M through the openings O1.

In the embodiment, the metal wire M includes a plurality of openings O2, and the passivation layer PV3 is filled in the openings O2 to increase a contact area between the metal wire M and the passivation layer PV3.

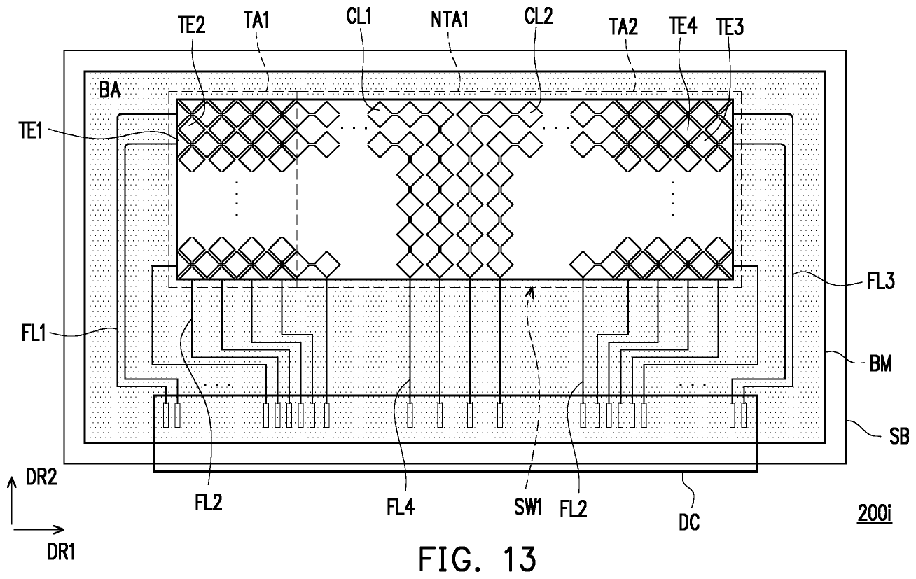

FIG. 13 is a schematic top view of a touch panel according to the invention.

Referring to FIG. 13, a touch panel 200i is overlapped with the display panel and has a first display area TA1, a second display area TA2, and a first connection area NTA1 located between the first display area TA1 and the second display area TA2.

The touch panel 200i includes a substrate SB, a plurality of first touch signal lines TE1, a plurality of second touch signal lines TE2, a plurality of first electrode lines TE3, a plurality of second electrode lines TE4, at least one driving chip DC, a plurality of first connection lines CL1, and a plurality of second connection lines CL2. In the embodiment, the touch panel 200i further includes a plurality of first circuit lines FL1, a plurality of second circuit lines FL2, a plurality of third circuit lines FL3, a plurality of fourth circuit lines FL4, and a light-shielding layer BM.

The first touch signal lines TE1 and the second touch signal lines TE2 are located on the first display area TA1. The first touch signal lines TE1 extend along the first direction DR1. The second touch signal lines TE2 extend along the second direction DR2. The first touch signal lines TE1 are staggered with the second touch signal lines TE2.

The first electrode lines TE3 and the second electrode lines TE4 are located on the second display area TA2. The first electrode lines TE3 extend along the first direction DR1. The second electrode lines TE4 extend along the second direction DR2. The first electrode lines TE3 are staggered with the second electrode lines TE4.

The driving chip DC, the first circuit lines FL1, the second circuit lines FL2, the third circuit lines FL3, and the fourth circuit lines FL4 are disposed on a peripheral area BA of the substrate SB, where the peripheral area BA is located outside the first display area TA1, the second display area TA2 and the first connection area NTA1. In the embodiment, the touch display device, for example, has one driving chip DC, but the invention is not limited thereto. In other embodiments, the touch display device may have a plurality of driving chips DC. The driving chip DC is, for example, electrically connected to the first circuit lines FL1, the second circuit lines FL2, the third circuit lines FL3, and the fourth circuit lines FL4 through a flexible circuit board (not shown). The driving chip DC is disposed at a first side SW1 of the first connection area NTA1.

The first connection lines CL1 are located on the first connection area NTA1, and electrically connect the first touch signal lines TE1 to the driving chip DC. The first connection lines CL1 extend from the first display area TA1 into the first connection area NTA1 in a direction parallel to the first direction DR1, and at least part of the first connection lines CL1 is turned toward the first side SW1 in the first connection area NTA1. The second connection lines CL2 are located on the first connection area NTA1 and electrically connect the first electrode lines TE3 to the driving chip DC. The second connection lines CL2 extend from the second display area TA2 into the first connection area NTA1 in a direction parallel to the first direction DR1, and at least part of the second connection lines CL2 is turned toward the first side SW1 in the first connection area NTA1.

In the embodiment, the first touch signal lines TE1, the first connection lines CL1, the first electrode lines TE3, and the second connection lines CL2 include a transparent conductive material. In the embodiment, the transparent conductive material in the first display area TA1, the second display area TA2, and the first connection area NTA1 makes the first display area TA1, the second display area TA2, and the first connection area NTA1 to have a close transmittance, which reduce a transmittance difference of the touch display device in the first display area TA1, the second display area TA2, and the first connection area NTA1.

The first circuit lines FL1 are electrically connected to the first touch signal lines TE1. The third circuit lines FL3 are electrically connected to the first electrode lines TE3. The second circuit lines FL2 are electrically connected to the second touch signal lines TE2 and the fourth electrode lines TE4. The fourth circuit lines FL4 are electrically connected to the first connection lines CL1 and the second connection lines CL2, where the fourth circuit lines FL4 are connected to the first connection lines CL1 and the second connection lines CL2 at the first side SW1 of the first connection area NTA1.

In the embodiment, the touch display panel has the display function in areas corresponding to the first display area TA1, the second display area TA2, and the first connection area NTA1. In the embodiment, the first display area TA1 and the second display area TA2 have the touch function, while the first connection area NTA1 does not have the touch function.

Although in the embodiment, the second display area TA2 has the touch function, the invention is not limited thereto. In other embodiments, the first electrode lines TE3 and/or the second electrode lines TE4 on the second display area TA2 are not electrically connected to the driving chip DC, so that the second display area TA2 does not have the touch function. In other words, in other embodiments, the touch display device does not include the third circuit lines FL3 electrically connected to the first electrode lines TE3, the second connection lines CL2, and a part of the four circuit lines FL4 electrically connected to the second connection lines CL2, and/or does not include a part of the second circuit lines FL2 electrically connected to the second electrode lines TE4.

In summary, only one touch panel is required to be attached to the display panel, and the touch display panel may have a plurality of touch areas separated from each other, thereby improving a production capacity of the touch display panels and reducing inspection times required in manufacturing of the touch display panels.

What is claimed is:

1. A touch display device, comprising:
a display panel; and
a touch panel, overlapped with the display panel, and having a first display area, a second display area, and a first connection area located between the first display area and the second display area, wherein the touch panel comprises:
a substrate;
a plurality of first touch signal lines and a plurality of second touch signal lines, located on the first display area, wherein the first touch signal lines extend along a first direction, and the second touch signal lines extend along a second direction;
a plurality of first electrode lines and a plurality of second electrode lines, located on the second display area, wherein the first electrode lines extend along the first direction, and the second electrode lines extend along the second direction, wherein materials of the first touch signal lines, the second touch signal lines, the first electrode lines, and the second electrode lines comprise a transparent conductive material; and
a plurality of first connection lines, located on the first connection area, and extending along the first direction, wherein the first connection lines are electrically connected to the first touch signal lines and at least part of the first electrode lines.

2. The touch display device as claimed in claim 1, wherein
the first touch signal lines, the first connection lines, and the at least part of the first electrode lines comprise a same material, and each of the first touch signal lines, a corresponding one of the first connection lines, and a corresponding one of the first electrode lines are connected as a whole.

3. The touch display device as claimed in claim 1, further comprising:
a plurality of floating electrodes, located on the first connection area, and extending along the second direction, wherein a material of the floating electrodes comprises the transparent conductive material.

4. The touch display device as claimed in claim 1, wherein
the first touch signal lines, the first connection lines, and the at least part of the first electrode lines are sequentially connected, and the first connection lines comprise metal wires.

5. The touch display device as claimed in claim 1, wherein an area of the first display area is smaller than an area of the second display area.

6. The touch display device as claimed in claim 1, further comprising:
at least one driving chip;
a plurality of first circuit lines, electrically connecting the at least one driving chip to the first touch signal lines; and
a plurality of second circuit lines, electrically connecting the at least one driving chip to the second touch signal lines and the second electrode lines, wherein the first circuit lines, the second circuit lines, and the at least one driving chip are disposed on a peripheral area of the substrate, and the peripheral area is located outside the first display area, the second display area, and the first connection area.

7. The touch display device as claimed in claim 6, further comprising:
a light-shielding layer, disposed on the peripheral area and the first connection area, and the light-shielding layer exposing the first display area and the second display area.

8. The touch display device as claimed in claim 6, further comprising:
a light-shielding layer, disposed on the peripheral area, and the light-shielding layer exposing the first display area, the first connection area, and the second display area.

9. The touch display device as claimed in claim 6, wherein the at least one driving chip is disposed close to one side of the substrate.

10. The touch display device as claimed in claim 6, wherein a part of the first circuit lines and the first connection lines are respectively connected to the first electrode lines.

11. The touch display device as claimed in claim 6, further comprising:
a plurality of second connection lines, extending along the first direction, and located on a second connection area, wherein the second connection area is located between the peripheral area and the second display area, wherein the second connection lines are electrically connected to a part of the first circuit lines, and the second connection lines are aligned with and are electrically connected to another part of the first electrode lines in the first direction.

12. The touch display device as claimed in claim 11, wherein the second connection lines comprise the transparent conductive material.

13. The touch display device as claimed in claim 11, further comprising:
a plurality of floating electrodes, extending along the second direction, and staggered with the first connection lines and the second connection lines, wherein a part of the floating electrodes is aligned with the second touch signal lines, and is separated from the second touch signal lines in the second direction.

14. A touch display device, comprising:
a display panel; and
a touch panel, overlapped with the display panel, and having a first display area, a second display area, and a first connection area located between the first display area and the second display area, wherein the touch panel comprises:
a substrate;
a plurality of first touch signal lines and a plurality of second touch signal lines, located on the first display area, wherein the first touch signal lines extend along a first direction, and the second touch signal lines extend along a second direction;
a plurality of first electrode lines and a plurality of second electrode lines, located on the second display area, wherein the first electrode lines extend along the first direction, and the second electrode lines extend along the second direction;
at least one driving chip, disposed at a first side of the first connection area; and
a plurality of first connection lines, located on the first connection area, and electrically connecting the first touch signal lines to the at least one driving chip, wherein the first connection lines extend from the first display area into the first connection area in a direction parallel to the first direction, and at least part of the first connection lines is turned toward the first side in the first connection area, wherein materials of the first touch signal lines, the first connection lines, and the first electrode lines comprise a transparent conductive material.

15. The touch display device as claimed in claim 14, further comprising:
a plurality of first circuit lines, electrically connecting the at least one driving chip to the first touch signal lines;
a plurality of second circuit lines, electrically connecting the at least one driving chip to the second touch signal lines and the second electrode lines; and
a plurality of third circuit lines, electrically connecting the at least one driving chip to the first electrode lines, wherein the first circuit lines, the second circuit lines, the third circuit lines, and the at least one driving chip are disposed on a peripheral area of the substrate, and the peripheral area is located outside the first display area, the second display area, and the first connection area.

16. The touch display device as claimed in claim 15, further comprising:
a plurality of second connection lines, located on the first connection area, and electrically connecting the first electrode lines to the at least one driving chip, wherein the second connection lines extend from the second display area into the first connection area in a direction parallel to the first direction, and at least part of the second connection lines is turned toward the first side in the first connection area, wherein a material of the second connection lines comprises the transparent conductive material.

17. The touch display device as claimed in claim 16, further comprising:
a plurality of fourth circuit lines, electrically connecting the at least one driving chip to the first connection lines and the second connection lines, wherein the fourth circuit lines are connected to the first connection lines and the second connection lines at the first side of the first connection area.
